(19) United States
(12) Patent Application Publication
(10) Pub. No.: US 2010/0112742 A1
(43) Pub. Date: May 6, 2010

(54) Nitride semiconductor device and method for making same

(75) Inventors: Kyu Han Lee, Suwon (KR); Je Won Kim, Suwon (KR); Dong Joon Kim, Suwon (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: Samsung Electro-Mechanics Co., Ltd., Suwon (KR)

(21) Appl. No.: 12/655,438

(22) Filed: Dec. 30, 2009

Related U.S. Application Data
(62) Division of application No. 11/332,688, filed on Jan. 13, 2006.

(30) Foreign Application Priority Data
Apr. 6, 2005 (KR) 10-2005-0028668

(51) Int. Cl. H01L 21/20

(52) U.S. Cl. 438/47; 257/E21.09

(57) ABSTRACT

A method of forming a nitride semiconductor device is disclosed. An n-type GaN layer is formed on a substrate. A self assembled nitride semiconductor quantum dot layer is formed on the n-type GaN layer by growing In_{y}Ga_{(1-y)}N (0.3≦y≦1) directly on the n-type GaN layer. A resonance tunnel layer is formed on the n-type GaN layer to cover the nitride semiconductor quantum dot layer. An active layer is formed on the resonance tunnel layer. A p-type nitride semiconductor layer is formed on the active layer. The active layer contains a quantum well layer and a quantum barrier layer, and the resonance tunnel layer has a band gap energy greater than that of the quantum well layer.

### CROSS REFERENCE TO RELATED APPLICATIONS

This application is a divisional of U.S. patent application Ser. No. 11/332,688, filed Jan. 13, 2006, which claims the benefit of Republic of Korea Patent Application No. 10-2005-0028668, filed Apr. 6, 2005, which are incorporated by reference as if fully set forth.

### FIELD OF INVENTION

The present invention relates to a nitride semiconductor device. More particularly, the present invention relates to a high-efficiency nitride semiconductor device which can optimize the capture rate of electrons injected into an active layer to increase internal quantum efficiency and reduce stress that causes piezoelectric field in the active layer.

### DESCRIPTION OF THE RELATED ART

In general, a nitride semiconductor is widely used for green or blue light emitting diodes (LEDs) which serve as a light source for full-color displays, image scanners, various signal systems and optical communication devices, or laser diodes (LDs). Such a nitride semiconductor device has an active layer including a single quantum well (SQW) structure or a multiple quantum well (MQW) structure arranged between n-type and p-type nitride semiconductor layers. Also, the active layer generates a specific wavelength light by recombination of electrons and holes.

Light efficiency of the nitride semiconductor device is determined fundamentally by the recombination rate for electrons and holes in the active layer, or internal quantum efficiency. Studies involving methods for enhancing internal quantum efficiency have been directed at improving a structure of the active layer or increasing the effective mass of carriers.

Especially, to boost the effective mass of carriers in the active layer, the number of carriers recombined outside the active layer should be reduced so that the capture rate for electrons and holes needs to be optimized. But, due to electron mobility relatively bigger than hole mobility, some electrons are not recombined in the active layer but move to a p-type nitride semiconductor layer where the electrons are recombined outside the active layer, thereby degrading light emitting efficiency.

Conventionally, U.S. Pat. No. 6,614,060 (published on Sep. 2, 2003, assigned to Arima Optoelectronics Corporation) discloses a method for employing an asymmetric resonance tunneling structure in which an InGaN/GaN layer is interposed between an n-type nitride semiconductor layer and an active layer.

FIGS. 1a and 1b illustrate a schematic structure and a band diagram of a nitride semiconductor device according to the aforesaid patent.

A nitride semiconductor device 10 shown in FIG. 1a includes a sapphire substrate 11 having a buffer layer 12 formed thereon. An n-type nitride semiconductor layer 13, an active layer 16, and a p-type nitride semiconductor layer 17 are formed in their order on the buffer layer 12. An n-electrode 18 is connected to the n-type nitride semiconductor layer 13 and a p-electrode 19 is connected to the p-type nitride semiconductor layer 16.

The aforesaid patent suggests an electron-emitting layer structure 15 formed between the n-type nitride semiconductor layer 13 and an active layer 16. The electron-emitting layer structure 15 includes an InGaN electron accumulation layer 15a and a GaN resonance tunnel layer 15b. The electron-emitting layer 15 serves to reduce the number of electrons that enter the p-type nitride semiconductor layer 17 without being recombined in the active layer 16.

More specifically, referring to FIG. 1b, the InGaN electron accumulation layer 15a has band gap smaller than that of the GaN n-nitride semiconductor layer 13. The GaN resonance tunnel layer 15b has band gap bigger than that of a quantum well layer and is formed in a thickness that allows tunneling.

Electrons provided by the n-type nitride semiconductor layer 13 are accumulated in the InGaN electron accumulation layer 15a having low band gap. The accumulated electrons are tunneled through the GaN resonance tunnel layer 15a and injected into the active layer 16. In this fashion, the electron-emitting layer 15 captures electrons and then injects the same into an active layer, thereby increasing the effective mass of electrons recombined in the active layer.

But according to the aforesaid method, the InGaN electron accumulation layer 15a should have band gap sufficiently smaller than that of adjacent n-type nitride semiconductor layer 13 and, for example, be as thick as about 50 nm so that lattice constant difference causes great stress.

Stress resulting from such lattice constant difference not only degrades crystalinity of the active layer considerably but also aggravates effects of piezoelectric field on the active layer. Especially, piezoelectric field separates wave functions of electrons and holes from one another, thus lowering electron-hole recombination rate. This severely deteriorates light emitting efficiency of the device.

### SUMMARY

The present invention has been made to solve the foregoing problems of the prior art and it is therefore an object of the present invention to provide a nitride semiconductor device having a novel electron-emitting structure which reduces stress-induced crystalline degradation of the active layer and effects of piezoelectric field, and captures electrons effectively under the active layer to increase electron-hole recombination rate.

According to an aspect of the invention for realizing the object, there is provided a nitride semiconductor device comprising: an n-type nitride semiconductor layer; a p-type nitride semiconductor layer; an active layer formed between the p-type nitride semiconductor layer and the n-type nitride semiconductor layer and having a quantum well layer and a quantum barrier layer; and an electron-emitting layer formed between the n-type nitride semiconductor layer and the active layer; wherein the electron-emitting layer comprises: a nitride semiconductor quantum dot layer formed on the n-type nitride semiconductor layer, and having a composition expressed by AlₓIn_{y}Ga_{(1-x-y)}N, where 0≦x≦1 and 0≦y≦1, and a resonance tunnel layer formed on the nitride semiconductor quantum dot layer, and having energy band gap bigger than that of the quantum well layer.

Preferably, the nitride semiconductor quantum dot layer has a thickness ranging from 1 monolayer to 50 Å. More preferably, the nitride semiconductor quantum dot layer has a thickness of 10 to 30 Å.

The semiconductor quantum dot layer employed in the invention has lattice constant difference from adjacent n-type nitride semiconductor layer and can be formed by stress resulting from the difference. Lattice constant difference for forming the quantum dot layer can be achieved by varying In content. Preferably, the nitride semiconductor quantum dot layer has a composition expressed by AlₓIn_{y}Ga_{(1-x-y)}N, where 0≦x≦1 and 0<y≦1, and the n-type nitride semiconductor layer has a composition expressed by Alₓ₁In_{y1}Ga_{(1-x1-y1)}N, where 0≦x₁≦1 and 0≦y₁≦1, wherein y is at least 0.3 greater than y1.

More preferably, the nitride semiconductor quantum dot layer has a composition expressed by In_{y}Ga_{(1-y)}N and the n-type nitride semiconductor layer is made of GaN, wherein y ranges from 0.3 to 1.

Preferably, the resonance tunnel layer has a thickness of about 0.5 to 10 m so that electrons captured in the nitride semiconductor quantum dot layer can be tunneled. In case where the resonance tunnel layer has a composition expressed by In_{y2}Ga_{(1-y2)}N, to have a desired energy band gap, In content (y) should be preferably 0.2 or less. Preferably, the resonance tunnel layer has a composition identical to that of the quantum barrier layer.

The resonance tunnel layer comprises an undoped layer or an n-doped layer. Preferably, the resonance tunnel layer is n-doped to a concentration of 10²⁰/cm³ or less.

### BRIEF DESCRIPTION OF THE DRAWINGS

The patent or application file contains at least one drawing executed in color. Copies of this patent or patent application publication with color drawing(s) will be provided by the Office upon request and payment of the necessary fee. Specifically, FIGS. 4(a)-(c) show Atomic Force Microscopy (AFM) color pictures.

The above and other objects, features and other advantages of the present invention will be more clearly understood from the following detailed description taken in conjunction with the accompanying drawings, in which:

FIG. 1a is a side sectional view of a conventional nitride semiconductor device;

FIG. 1b is an energy band diagram of the nitride semiconductor device shown in FIG. 1a;

FIG. 2 is a side sectional view of a nitride 10 semiconductor device according to an embodiment of the invention;

FIG. 3 is a TEM picture showing a side sectional view of a structure in which an InGaN layer and an InN quantum dot layer are grown repeatedly;

FIG. 4a and FIG. 4b are AFM pictures showing a surface of an active layer employed in a conventional nitride semiconductor device;

FIG. 4c is an AFM picture showing a surface of an active layer employed in a nitride semiconductor device according to the invention;

FIG. 5a and FIG. 5b are graphs illustrating the measured results of photoluminescence (PL) of an electron-emitting layer/an active layer employed in the nitride semiconductor device according to the prior art and the invention.

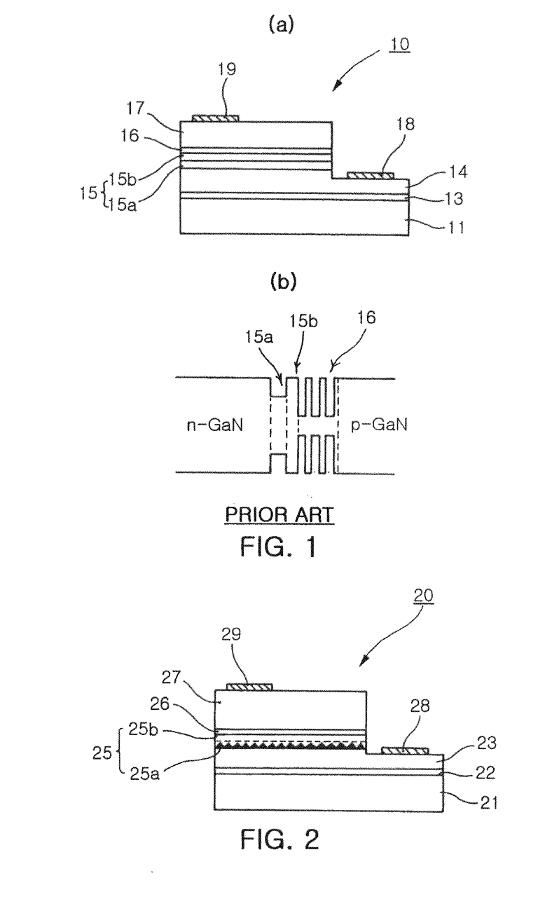

### DETAILED DESCRIPTION OF THE PREFERRED EMBODIMENTS

Preferred embodiments of the present invention will now be described in detail with reference to the accompanying drawings.

FIG. 2 is a side sectional view illustrating a nitride semiconductor device according to an embodiment of the invention.

As shown in FIG. 2, a nitride semiconductor device 20 includes a sapphire substrate 21 having a buffer layer 22 formed thereon. The buffer layer 22 may be a nitride layer grown at a low temperature. An n-type nitride semiconductor layer 23, an active layer 26 and a p-type nitride semiconductor layer 27 are sequentially formed on the buffer layer 22. Also, an n-electrode 28 is connected to the n-type nitride semiconductor layer 23 and a p-type electrode 29 is connected to the p-type nitride semiconductor layer 26.

The nitride semiconductor layer 20 according to the invention has a novel electron-emitting layer structure 25 between the n-type nitride semiconductor layer 23 and the active layer 26. The electron-emitting layer 25 includes a nitride semiconductor quantum dot layer 25a and a resonance tunnel layer 25b.

Unlike a conventional electron accumulation method using a layer structure with low band gap, the electron-emitting layer 25 according to the invention uses quantum dots having a quantum structure in which carriers have zero-dimensional degree of freedom. Unlike the band gap principle, the nitride semiconductor quantum dot layer 25a employed as electron accumulation structure in the invention constrains and accumulates electrons three-dimensionally. Also, unlike a typical thick crystal layer structure, the nitride semiconductor quantum dot layer 25a does not adversely affect crystalinity of the nitride layer grown later (e.g. active layer).

The nitride semiconductor quantum dot layer 25a is formed on the n-type nitride semiconductor layer 23 and has a composition expressed by AlₓIn_{y}Ga_{(1-x-y)}N, where 0≦x≦1 and 0≦y≦1. While various known methods for forming quantum dots on the nitride semiconductor quantum dot layer 25a may be employed, the quantum dots are formed preferably via self-assembling using proper lattice constant difference from the n-type nitride semiconductor layer 23. That is, when a layer having lattice difference grows two-dimensionally with strong binding capacity, the growing layer suffers from increasing internal stress as its thickness gets greater. But when the thickness reaches the critical value, quantum dots of three-dimensional islands are formed spontaneously to relieve stress. Lattice constant difference necessary for the formation of quantum dots can be controlled by composition content difference from the n-type nitride semiconductor layer. Preferably, lattice constant difference can be controlled by In content.

For example, when the n-type nitride semiconductor layer 23 has a composition expressed by AlₓIn_{y1}Ga_{(1-x-y1)}N, where 0≦x₁≦1 and 0y₁<1, the nitride semiconductor quantum dot layer 25a may be formed of nitride having a composition expressed by AlₓIn_{y}Ga_{(1-x-y)}N in which y is at least 0.3 greater than y₁. In other specific example, in case where the n-type nitride semiconductor layer 23 is made of GaN, the nitride semiconductor quantum dot layer 25a may be formed of nitride having a composition expressed by In_{y}Ga_{(1-y)}N, where 0.3≦y≦1.

Further, the nitride semiconductor quantum dot layer 25a should be formed in at least a thickness that allows formation of desired quantum dots (that is, critical thickness for self-assembled formation). On the other hand, the nitride semiconductor quantum dot layer 25a should be formed in an adequate thickness so as not to grow into a crystal layer structure. Preferably, the quantum dot layer has a thickness ranging from 1 monolayer (ML) to 50 Å, and more preferably about 10 to 30 Å.

The resonance tunnel layer 25b is formed on the nitride semiconductor quantum dot layer 25a and has energy band gap bigger than that of a quantum well layer (not illustrated) of adjacent active layer 26. The resonance tunnel layer 25b has an adequate thickness so that electrons accumulated in the quantum dot layer 25a can be tunneled into the active layer 26. Preferably, the resonance tunnel layer 25b has a thickness of about 0.5 to 10 nm. The resonance tunnel layer 25b has a composition expressed by In_{y2}Ga_{(1-y2)}N, in which desired In content y₂ is 0.2 or less but not limited thereto. Herein, y₂ has energy band gap bigger than that of adjacent quantum well layer.

The resonance tunnel layer 25b may have a composition identical to that of a quantum barrier layer (not shown) of the active layer 26. Also, the resonance tunnel layer 25b is an undoped layer or n-doped layer. In the case of n-type resonance tunnel layer, preferably, it is n-doped to a concentration of 10²⁰/cm³or less.

The nitride semiconductor device according to the invention has electron accumulation structure as described above. Therefore the device uses quantum dots instead of a crystal layer having a predetermined thickness, thereby enhancing the capture rate of electrons. This also does not trigger stress resulting from lattice constant difference. Consequently, the active layer achieves good crystalinity. This prevents decrease in electron-hole recombination rate, which inevitably arose from the conventional electron-emitting layer structure.

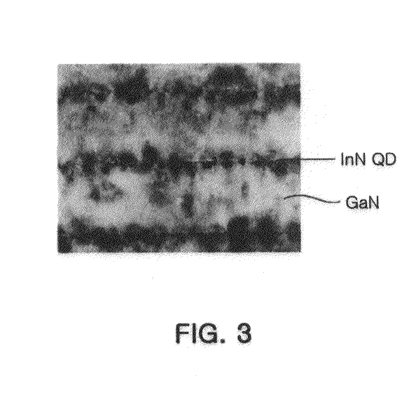

FIG. 3 is a TEM picture showing a structure in which a GaN layer and an InN quantum dot layer are grown repeatedly, as a result of tests showing the formation of the nitride semiconductor quantum dot layer employed in the invention.

It was confirmed that a thin InN layer having quantum dot structure was formed on the GaN layer when about 10 nm GaN layer, typically used as an n-type nitride semiconductor layer, and about 30 Å InN layer were grown three times. It can be understood that the InN quantum dot layer was formed by stress resulting from lattice constant difference from GaN. It was also confirmed that the GaN layer formed on the InN quantum dot layer through repetitive growth exhibited great crystalinity.

By comparing Inventive Example with Comparative Examples according to prior art, an explanation will be given in greater detail hereunder regarding improved crystalinity and electron capture rate to be achieved in the invention.

### Example

An n-type GaN layer was formed on a sapphire substrate and then an InN quantum dot layer having a thickness of about 15 Å was formed as an electron accumulation layer. Thereafter, an GaN layer having a thickness of about 10 Å was formed on the InN quantum dot layer as a resonance tunnel layer. Then, an active layer having an In_{0.3}Ga_{0.7}N quantum well layer with a thickness of 10 Å and a GaN quantum barrier layer with a thickness of 15 Å was formed.

### Comparative Example 1

Layers were grown under the same conditions as in Inventive Example. But an active layer was directly formed on the n-type GaN layer without forming an electron accumulation layer and a resonance tunnel layer structure.

### Comparative Example 2

Layers were grown under the same conditions as in Inventive Example and Comparative Example 1 except for an electron accumulation layer and a resonance tunnel layer of electron-emitting structure. That is, an electron accumulation layer of In₀₃Ga₀₇N was grown on an n-type GaN layer to a thickness of about 50 nm.

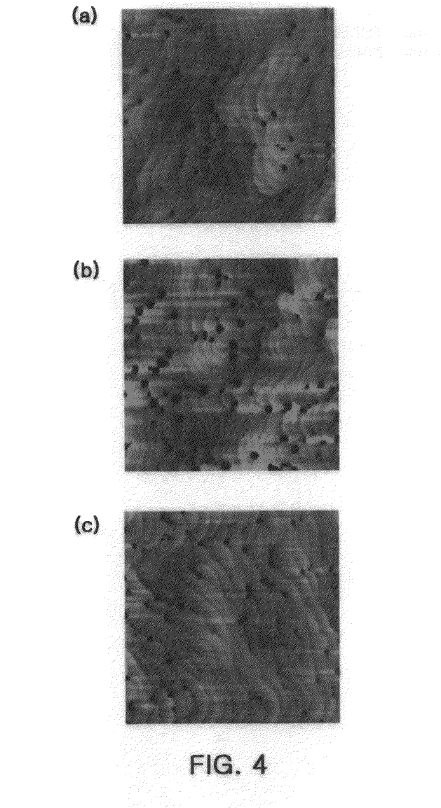

Final surfaces (5×5 μm) of active layers obtained from Comparative Examples 1,2 and Inventive Example were photographed with AFM. FIGS. 4a to 4c are AFM pictures showing the final surface of each active layer.

First, in Comparative Example 1 (refer to FIG. 4a), relatively small number of pits were found. This pit number resulted inevitably from the crystallization conditions. In contrast, Comparative Example 2 (refer to FIG. 4b) showed relatively larger number of pits than in FIG. 4a. Such a pit number denotes that crystalinity was considerably degraded compared to Comparative Example 1 in which electron-emitting structure was not employed in an active layer. This was caused by stress which arose due to a relatively thick electron accumulation layer.

On the other hand, Inventive Example (FIG. 4c) showed only a small number of pits similar to Comparative Example 1 in which the electron-emitting layer was not employed. In Inventive Example, electron-emitting structure was used to increase recombination efficiency. But herein, as the electron accumulation layer, quantum dots were used instead of a thick crystal layer using energy band gap difference as in Comparative Example 2.

The test results show that electron-emitting structure using quantum dots according to the invention does not degrade crystalinity of the active layer, thus preventing the disadvantage of increasing effects of piezoelectric field on the active layer as in the conventional electron-emitting structure.

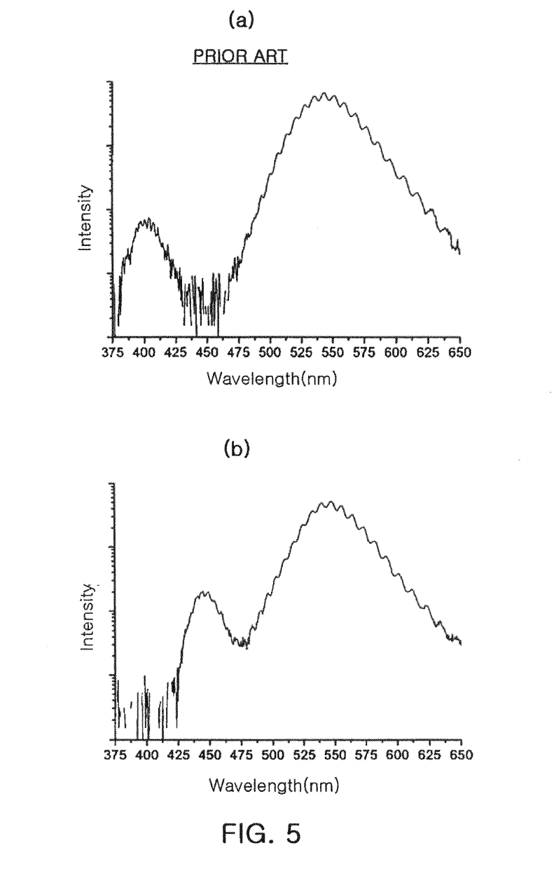

Also, to confirm electron capture rate of the nitride semiconductor quantum dot layer employed in the invention, photoluminescence (PL) was measured in Inventive Example and Comparative Example 2. FIGS. 5a and 5b are graphs illustrating measured results of PL according to Comparative Example 2 and Inventive Example.

The PL graph (Comparative Example 2) of FIG. 5a showed a peak around 400 nm resulting from an InGaN electron accumulation layer. The PL graph (Inventive Example) of FIG. 5b exhibited a peak around 440 nm resulting from an InN semiconductor quantum dot layer. Especially, the InN semiconductor quantum dot layer according to Inventive Example has a peak bigger than that of FIG. 5a. This confirms that the semiconductor quantum dot layer according to the invention has higher electron capture rate than the conventional electron accumulation layer using energy band gap.

As stated above, according to the invention, the nitride semiconductor device employs semiconductor quantum dots as the electron accumulation layer in electron-emitting structure. This leads to more effective capture of electrons and increase in the recombination rate. Also, this prevents stress-induced crystalline degradation of the active layer, and reduces effects of piezoelectric field, thereby markedly enhancing internal quantum efficiency.

While the present invention has been shown and described in connection with the preferred embodiments, it will be apparent to those skilled in the art that modifications and variations can be made without departing from the spirit and scope of the invention as defined by the appended claims.

What is claimed is:

1. A method of forming a nitride semiconductor device, comprising:
forming an n-type GaN layer on a substrate;
forming a self assembled nitride semiconductor quantum dot layer on the n-type GaN layer by growing In_{y}Ga_{(1-y)}N (0.3≦y≦1) directly on the n-type GaN layer;
forming a resonance tunnel layer on the n-type GaN layer to cover the nitride semiconductor quantum dot layer;
forming an active layer on the resonance tunnel layer, the active layer comprising a quantum well layer and a quantum barrier layer, the resonance tunnel layer having a band gap energy greater than the band gap energy of the quantum well layer; and
forming a p-type nitride semiconductor layer on the active layer.

2. The method of forming a nitride semiconductor device according to claim 1, wherein the nitride semiconductor quantum dot layer has a thickness ranging from 1 monolayer to 50 Å.

3. The method of forming a nitride semiconductor device according to claim 2, wherein the nitride semiconductor quantum dot layer has a thickness of 10 to 30 Å.

4. The method of forming a nitride semiconductor device according to claim 1, wherein the resonance tunnel layer has a thickness of 0.5 to 10 nm.

5. The method of forming a nitride semiconductor device according to claim 1, wherein the resonance tunnel layer has a composition expressed by In_{y2}Ga_{(1-y2)}N where y2 is 0.2 or less.

6. The method of forming a nitride semiconductor device according to claim 1, wherein the resonance tunnel layer has a composition identical to that of the quantum barrier layer.

7. The method of forming a nitride semiconductor device according to claim 1, wherein the resonance tunnel layer comprises an undoped layer.

8. The method of forming a nitride semiconductor device according to claim 1, wherein the resonance tunnel layer is n-doped to a concentration of 10²⁰/cm³ or less.
